(19) United States
(12) Patent Application Publication
(10) Pub. No.: US 2025/0301667 A1
(43) Pub. Date: Sep. 25, 2025

(54) SEMICONDUCTOR DEVICE WITH NON-PLANAR MOSFET DEVICE DIE AND PLANAR MOSFET DEVICE DIE

(71) Applicant: Silicon Storage Technology, Inc., San Jose, CA (US)

(72) Inventors: FENG ZHOU, Fremont, CA (US); DERKANT CHENG, Taipei City (CN); DAVID EGGLESTON, Willis, TX (US); XIAN LIU, Sunnyvale, CA (US); TING-HAO CHANG, Zhubei (TW); SHIJUN QI, Shanghai (CN); BO-CHANG WU, Taipei City (TW); CHAO-YU LIU, Taoyuan City (TW); SIMONE BARTOLI, Lecco (IT); LORENZO BEDARIDA, Vimercate (IT); NHAN DO, Saratoga, CA (US); MARK REITEN, Alamo, CA (US)

(21) Appl. No.: 18/637,265

(22) Filed: Apr. 16, 2024

(30) Foreign Application Priority Data
Mar. 20, 2024 (CN) 202410323760X

(51) Int. Cl. H10B 80/00; H01L 23/00; H01L 25/00; H01L 25/065; H01L 25/18

(52) U.S. Cl. CPC H10B 80/00; H01L 24/08; H01L 24/16; H01L 24/20; H01L 25/0655; H01L 25/0657; H01L 25/18; H01L 25/50; H01L 2224/08145; H01L 2224/16145; H01L 2224/214; H01L 2924/1431; H01L 2924/14511

(57) ABSTRACT

A semiconductor device comprising a first die and a second die. The first die comprises a first substrate, non-planar MOSFET devices formed on the first substrate, and first contact pads electrically connected to the non-planar MOSFET devices. The second die comprises a second substrate, planar MOSFET devices formed on the second substrate, and second contact pads electrically connected to the planar MOSFET devices. Insulation material is formed on the first and second substrates. Contacts are formed on the insulation material. Paths of conductive material extend through the insulation material, and electrically connect to respective ones of the contacts, the first contact pads and the second contact pads.

### RELATED APPLICATION

This application claims the benefit of Chinese Patent Application No. 202410323760X, filed Mar. 20, 2024, and which is incorporated herein by reference.

### FIELD OF THE INVENTION

The present invention relates to semiconductor devices, and in particular multi-die semiconductor devices.

### BACKGROUND OF THE INVENTION

Split-gate non-volatile memory devices are well known in the art. See for example U.S. Pat. No. 7,868,375, which discloses a four-gate memory cell configuration, and which is incorporated herein by reference for all purposes. Specifically, FIG. 1 of the present disclosure illustrates non-volatile memory cells, and in particular, a pair of split gate non-volatile memory cells 10, which each non-volatile memory cell 10 with spaced apart source and drain regions 14/16 formed in a silicon semiconductor substrate 12. The source region 14 can be referred to as a source line SL (because it commonly is connected to other source regions for other memory cells in the same row or column), and the drain region 16 is commonly connected to a bit line. A channel region 18 of the substrate 12 extends between the source/drain regions 14/16. A floating gate 20 is disposed over (i.e., vertically over and laterally overlapping) and insulated from (and directly controls the conductivity of) a first portion of the channel region 18 (and partially over and insulated from the source region 14). A control gate 22 is disposed over and insulated from the floating gate 20. A select gate 24 (also referred to as a word line gate) is disposed over and insulated from (and directly controls the conductivity of) a second portion of the channel region 18. An erase gate 26 is disposed over and insulated from the source region 14 and is laterally adjacent to the floating gate 20. The erase gate 26 can include a notch that faces an edge of the floating gate 20.

A plurality of such memory cells 10 can be arranged in rows and columns to form a memory cell array, as illustrated in FIG. 2. While FIG. 1 only shows a pair of memory cells 10 (sharing a common source region 14 and erase gate 26), the memory cell pairs can be placed end to end to form a column of memory cells (where the memory cell pairs can share a common drain region). While only two such columns are shown in FIG. 2, there can be many such columns. Each column can include a bit line 16a electrically connecting together all the drain regions 16 in the column. Each row of memory cells 10 can include a control gate line 22a electrically connecting together all the control gates 22 in the row of memory cells 10. For example, all the control gates 22 in each row of memory cells 10 can be formed as a continuous line of conductive material, where a portion of the continuous line passing through any given memory cell 10 serves as its control gate 22. Each row of memory cells 10 can include a select gate line 24a electrically connecting together all the select gates 24 in the row of memory cells 10. For example, all the select gates 24 in each row of memory cells 10 can be formed as a continuous line of conductive material, where a portion of the continuous line passing through any given memory cell 10 serves as its select gate 24. Each row of memory cell pairs can include an erase gate line 26a electrically connecting together all the erase gates 26 in the row of memory cell pairs. For example, all the erase gates 26 in each row of memory cell pairs can be formed as a continuous line of conductive material, where a portion of the continuous line passing through any given memory cell pair serves as its erase gate 26. Finally, each row of memory cell pairs can include a source line 14a electrically connecting together all the source regions 14 in the row of memory cell pairs. For example, all the source regions 14 in each row of memory cell pairs can be formed as a continuous line of conductive diffusion in the substrate 12, where a portion of the continuous line passing through any given memory cell pair serves as its source region 14.

Various combinations of voltages are applied to the control gate 22, select gate 24, erase gate 26 and source and drain regions 14/16, to program the split gate memory cell 10 (i.e., inject electrons onto the floating gate 20), to erase the split gate memory cell 10 (i.e., remove electrons from the floating gate 20), and to read the split gate memory cell 10 (i.e., measure or detect the conductivity of the channel region 18, by for example measuring or detecting a read current through the channel region 18, to determine the programming state of the floating gate 20).

Split gate memory cell 10 can be operated in a digital manner, where the split gate memory cell 10 is set to one of only two possible states: a programmed state and an erased state. The split gate memory cell 10 is erased by placing a high positive voltage on the erase gate 26, and optionally a negative voltage on the control gate 22, to induce tunneling of electrons from the floating gate 20 to the erase gate 26 (leaving the floating gate 20 in a more positively charged state—the erased state). Split gate memory cell 10 can be programmed by placing positive voltages on the control gate 22, erase gate 26, select gate 24 and source region 14, and a current on drain region 16. Electrons will then flow along the channel region 18 from the drain region 16 toward the source region 14, with electrons becoming accelerated and heated whereby some of them are injected onto the floating gate 20 by hot-electron injection (leaving the floating gate 20 in a more negatively charged state—the programmed state).

Split gate memory cell 10 can be read by placing positive voltages on the select gate 24 (turning on the portion of channel region 18 under the select gate 24 by making it conductive) and drain region 16 (and optionally on the erase gate 26 and the control gate 22), and sensing current flow through the channel region 18. If the floating gate 20 is positively charged (i.e. split gate memory cell 10 is erased), the split gate memory cell 10 will turn on because the both portions of the channel region 18 are conductive due to the lack of electrons on the floating gate 20, and electrical current will flow from drain region 16 to source region 14 (i.e. the split gate memory cell 10 is sensed to be in its erased “1” state based on sensed current flow). If the floating gate 20 is negatively charged (i.e. split gate memory cell 10 is programmed), the portion of channel region 18 under the floating gate is turned off (low conductivity), thereby preventing appreciable current flow (i.e., the split gate memory cell 10 is sensed to be in its programmed “0” state based on no, or minimal, current flow). Memory cells 10 are considered non-volatile because they maintain their program state even when power is not applied to the semiconductor device. Memory cells 10 can be referred to as split gate memory cells because two different gates (floating gate 20 and select gate 24), respectively, directly control the conductivity of two different portions of the channel region 18.

Split gate memory cell 10 can alternately be operated in an analog manner where the memory state (i.e. the amount of charge, such as the number of electrons, on the floating gate 20) of the split gate memory cell 10 can be incrementally changed anywhere from a fully erased state (minimum number of electrons on the floating gate 20) to a fully programmed state (maximum number of electrons on the floating gate 20), or just a portion of this range. This means the split gate memory cell 10 storage is analog, which allows for very precise and individual tuning of each split gate memory cell 10 in an array of split gate memory cells 10. Alternatively, the split gate memory cell 10 could be operated as an MLC (multilevel cell) where it is configured to be programmed to one of many discrete values (such as 16 or 64 different values).

Split gate memory cells with fewer gates are also known. For example, FIG. 3 illustrates known split gate memory cells 10 that are the same as that of FIG. 1, except the control gates 22 are omitted. See for example U.S. Pat. No. 7,315,056 which is incorporated herein by reference for all purposes. Voltage coupling to the floating gate 20 provided by the control gate 22 of the split gate memory cell of FIG. 1 is provided instead by the erase gate 26 and source region 14 of the split gate memory cell in FIG. 3. FIG. 4 illustrates an example layout of an array of the split gate memory cells 10 of FIG. 3.

As another example, FIG. 5 illustrates known split gate memory cells 10 that are similar to that of FIG. 1, except the control gates 22 and the erase gates 26 are omitted. See for example U.S. Pat. No. 5,029,130 which is incorporated herein by reference for all purposes. The erase voltage for the split gate memory cell of FIG. 5 is applied to the select gate 24, which has a first portion laterally adjacent the floating gate 20, and a second portion that extends up and over the floating gate 20. FIG. 6 illustrates an example layout of an array of the split gate memory cells 10 of FIG. 5.

As yet another example, FIG. 7 illustrates known split gate memory cells 10 that are similar to that of FIG. 5, except a conductive block of material 28 is formed in contact with source region 14, to serve as an extended source line. See for example U.S. Pat. No. 6,855,980 which is incorporated herein by reference for all purposes. An example layout for an array of the split gate memory cells 10 of FIG. 7 can be the same as that in FIG. 6.

In forming memory devices with split gate memory cells of the types described above, logic devices can be formed on the same substrate 12 containing the split gate memory cells 10. A logic device is shown in FIG. 8, and includes a source region 32 and a drain region 34 formed in the substrate 12. A channel region 36 of the substrate 12 extends between the source/drain regions 32/34. A conductive gate 38 is disposed over and insulated from (and directly controls the conductivity of) the channel region 36.

The split gate memory cells 10 of FIGS. 1-7, and logic device 30 of FIG. 8, are considered planar MOSFET devices because they utilize the semiconductor material under the planar surface of substrate 12 for the channel regions (i.e., the channel regions 18 and 36 extend along the substrate's upper surface which are planar).

To solve problems associated with reduced channel widths by shrinking lithography size, non-planar MOSFET devices have been proposed so that logic devices can be further reduced in size. One example of a non-planar MOSFET device is a FinFET device. In a FinFET device, a fin shaped member of semiconductor material connects the source and the drain regions. Specifically, the fin shaped member extends up from the substrate surface, having two side surfaces terminating in a top surface. Current flowing between the source and drain regions can flow along the top surface as well as the two side surfaces of the fin shaped member. Thus, the effective width of the channel region is increased, thereby increasing the current flow. The FinFET devices offer better electrostatic control of the channel which can switch off and on faster and results in better performance. However, the effective width of the channel region is increased without sacrificing more semiconductor real estate by “folding” the channel region into the two side surfaces and top surface of the fin, thereby reducing the size of the “footprint” of the channel region and therefore the non-planar device on the upper surface of the substrate.

FIGS. 9A and 9B illustrate a FinFET logic device 40, where the conductive gate 42 wraps around and is insulated from the channel region of the top surface and side surfaces of upwardly extending fin 12a of substrate 12. FIG. 9A is a side view of FinFET logic device 40 taken along line 9A-9A of FIG. 9B, and FIG. 9B is a side view taken along line 9B-9B of FIG. 9A. The source region 44 and drain region 46 are formed in the fin 12a, and the channel region 48 extends along the top and side surfaces of the fin 12a.

Another non-planar MOSFET device that has been proposed is a gate-all-around logic device (also known as GAAFET logic device). A gate-all-around logic device 50 is illustrated in FIGS. 10A and 10B, and includes wires of semiconductor material 52 extending through a conductive gate 54 that is disposed over and insulated from the substrate 12. FIG. 10A is a side view of GAAFET logic device 50 taken along line 10A-10A of FIG. 10B, and FIG. 10B is a side view taken along line 10B-10B of FIG. 10A. The source regions 56 and drain regions 58 are formed in portions of the wires of semiconductor material 52 adjacent the conductive gate 54. Respective channel regions 60 extend through the portion of the respective wire of semiconductor material 52 extending between the respective source region 56 and respective drain region 58 and through the conductive gate 54. With this configuration, the conductive gate 54 surrounds the channel regions 60. While three wires of semiconductor material 52 are shown, any number (i.e. one or more) of wires of semiconductor material 52 can be included in the GAAFET logic device 50.

The FinFET logic device 40 of FIGS. 9A-9B, and the GAAFET device 50 of FIGS. 10A and 10B are considered non-planar MOSFET devices because they utilize semiconductor material extending up from the surface of the substrate 12 or disposed above the surface of substrate 12 for the channel regions.

It can be beneficial to form non-planar MOSFET devices on the same substrate as planar MOSFET devices, so that the advantages of non-planar and planar MOSFET devices can be exploited in a single semiconductor device. For example, FinFET logic devices have been combined with planar split gate memory cells on the same substrate to reduce the size of the area of the substrate needed for the non-planar logic devices, and to utilize the performance advantages of planar split gate memory cells. See for example U.S. Pat. Nos. 11,315,940 and 11,594,453 (respectively incorporated herein by reference for all purposes) which disclose techniques for forming FinFET logic devices on the same substrate as planar split gate memory cells.

As lithography sizes continue to shrink, it is becoming more difficult to form non-planar MOSFET devices (such as FinFET or GAAFET logic devices) on the same substrate as planar MOSFET devices (such as planar split gate memory cells).

### BRIEF SUMMARY OF THE INVENTION

The aforementioned problems and needs are addressed by semiconductor device comprising a first die and a second die. The first die comprises a first substrate, non-planar MOSFET devices formed on the first substrate, and first contact pads electrically connected to the non-planar MOSFET devices. The second die comprises a second substrate, planar MOSFET devices formed on the second substrate, and second contact pads electrically connected to the planar MOSFET devices. Insulation material is formed on the first and second substrates. Contacts are formed on the insulation material. Paths of conductive material extend through the insulation material, and electrically connect to respective ones of the contacts, the first contact pads and the second contact pads.

A semiconductor device comprises a first die and a second die. The first die comprises a first substrate, non-planar MOSFET devices formed on the first substrate, and first contact pads electrically connected to the non-planar MOSFET devices. A second die comprises a second substrate, planar MOSFET devices formed on the second substrate, and second contact pads electrically connected to the planar MOSFET devices. Selected ones of the first contact pads are physically bonded to selected ones of the second contact pad. A conductive via or a wire is in electrical contact with one of the first or second contact pads.

A semiconductor device comprises a first die and a second die. The first die comprises a first substrate, non-planar MOSFET devices formed on the first substrate, and first contact pads electrically connected to the non-planar MOSFET devices. A second die comprises a second substrate, planar MOSFET devices formed on the second substrate, and second contact pads electrically connected to the planar MOSFET devices. Selected ones of the first contact pads are electrically connected to selected ones of the second contact pads by conductive pillars. A conductive via or a wire is in electrical contact with one of the first or second contact pads.

Other objects and features of the present disclosure will become apparent by a review of the specification, claims and appended figures.

### BRIEF DESCRIPTION OF THE DRAWINGS

FIG. 1 is a cross sectional view of a conventional pair of split gate memory cells.

FIG. 2 is a schematic and layout diagram of a conventional split gate memory cell array of the memory cells of FIG. 1.

FIG. 3 is a side cross sectional view of a conventional pair of split gate memory cells.

FIG. 4 is a schematic and layout diagram of a conventional memory cell array of the split gate memory cells of FIG. 3.

FIG. 5 is a side cross sectional view of a conventional pair of split gate memory cells.

FIG. 6 is a schematic and layout diagram of a conventional memory cell array of the split gate memory cells of FIG. 5.

FIG. 7 is a side cross sectional view of a conventional pair of split gate memory cells.

FIG. 8 is a side cross sectional view of a conventional planar logic device.

FIGS. 9A and 9B are side cross sectional views of a conventional FinFET logic device.

FIGS. 10A and 10B are side cross sectional views of a conventional gate-all-around FET (GAAFET) logic device.

FIGS. 11A-11D are side cross section views illustrating the fabrication of a semiconductor device according to a first example.

FIGS. 12A-12D are side cross section views illustrating the fabrication of a semiconductor device according to a second example.

FIGS. 13A-13B are side cross section views illustrating variants of the semiconductor device according to the second example.

FIGS. 14A-14E are side cross section views illustrating the fabrication of a semiconductor device according to a third example.

FIGS. 15A-15B are side cross section views illustrating variants of the semiconductor device according to the third example.

FIG. 16 is a side cross section views illustrating a semiconductor device according to another example.

FIGS. 17A-17B are side cross section views illustrating variants of the semiconductor device according to the example of FIG. 16.

FIG. 18 is a side cross section view illustrating a semiconductor device according to another example.

FIGS. 19A-19B are side cross section views illustrating variants of the semiconductor device according to the example of FIG. 18.

### DETAILED DESCRIPTION OF THE INVENTION

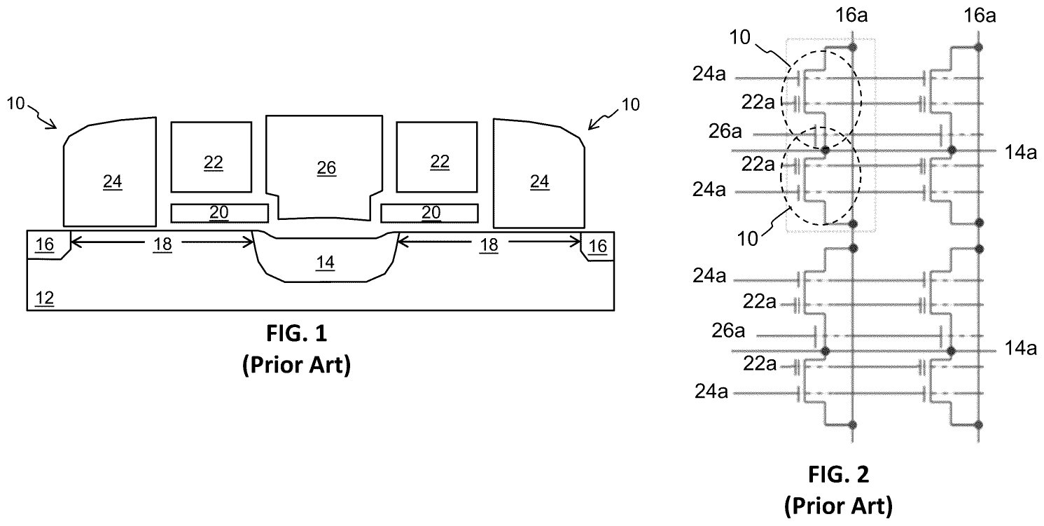

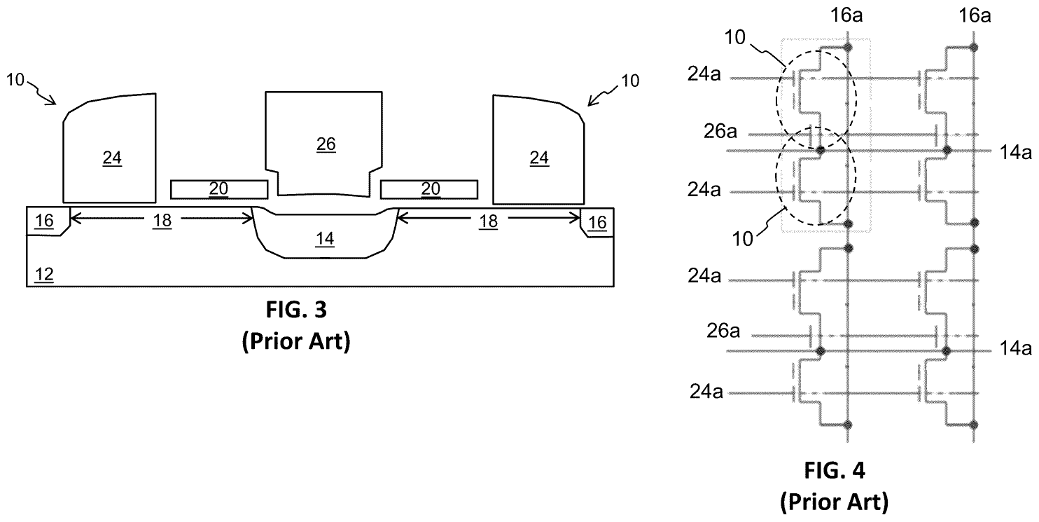

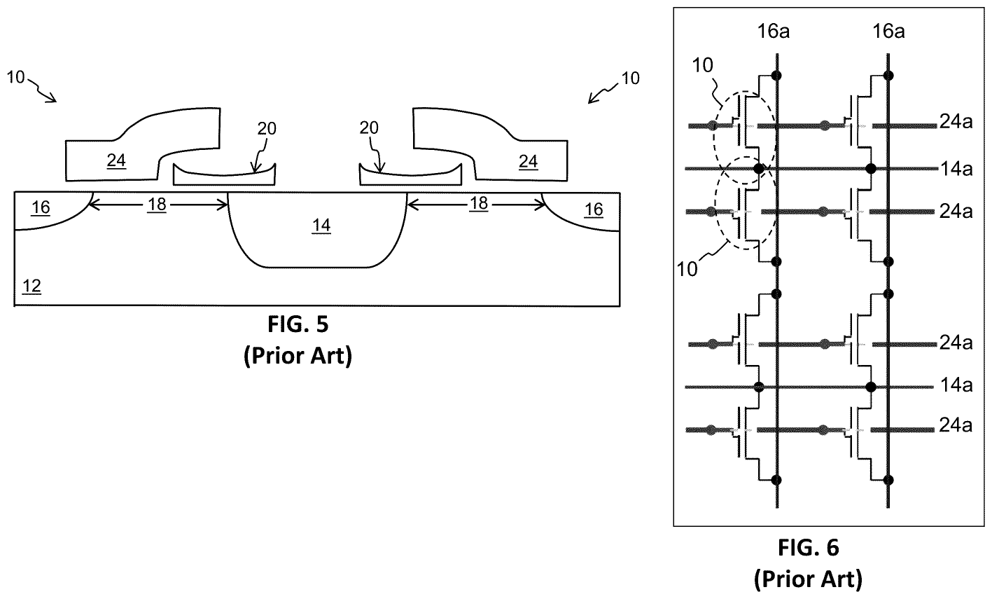

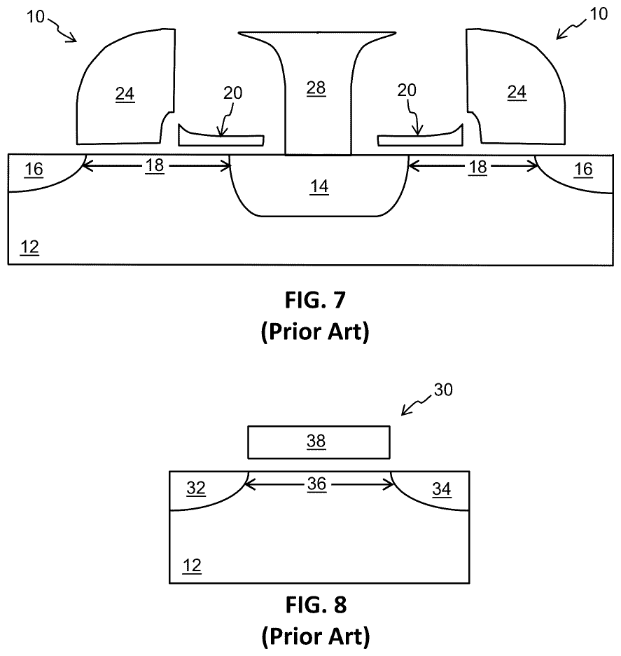

One semiconductor device configuration that can utilize non-planar MOSFET devices on the same substrate as planar MOSFET devices are systems-on-chip. A system-on-chip can include multiple functional blocks formed on a single substrate. For example, the following functional blocks can be formed on a single substrate and interconnected with wires, buses and networks on chip: a central processing unit (CPU), a graphics processing unit (GPU), volatile memory (SRAM), and non-volatile memory (NVM). The non-volatile memory (NVM) can be any of the planar split gate memory cells configurations shown in FIGS. 1-7. Each functional block contains circuits that perform specific functions. In order to scale down the size of the system-on-chip, some of the functional blocks can include non-planar devices such as FinFET logic devices (e.g., central processing unit (CPU), graphics processing unit (SRAM), volatile memory (SRAM)), while other functional blocks can include planar devices (e.g., non-volatile memory (NVM)).

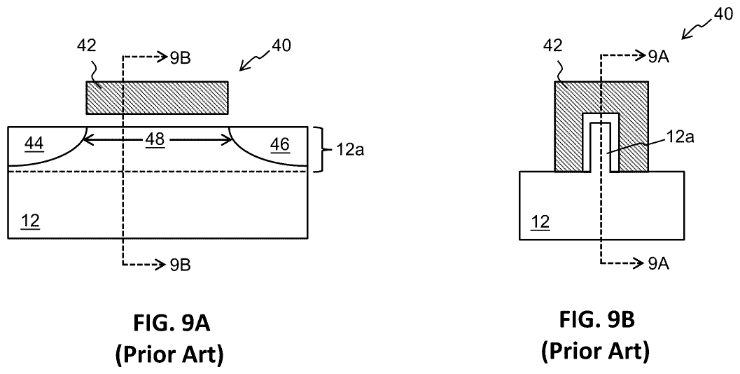

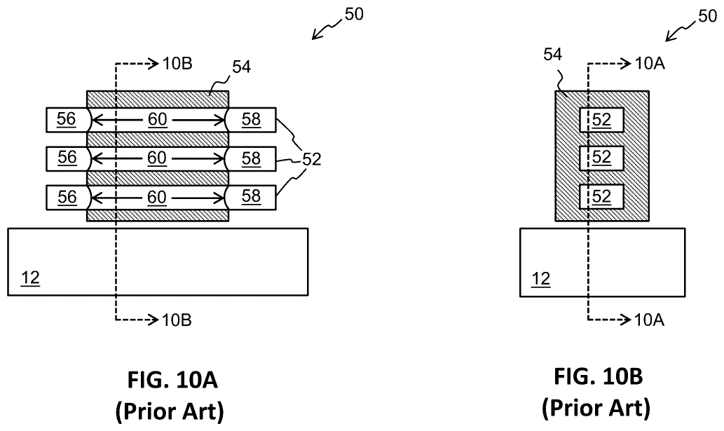

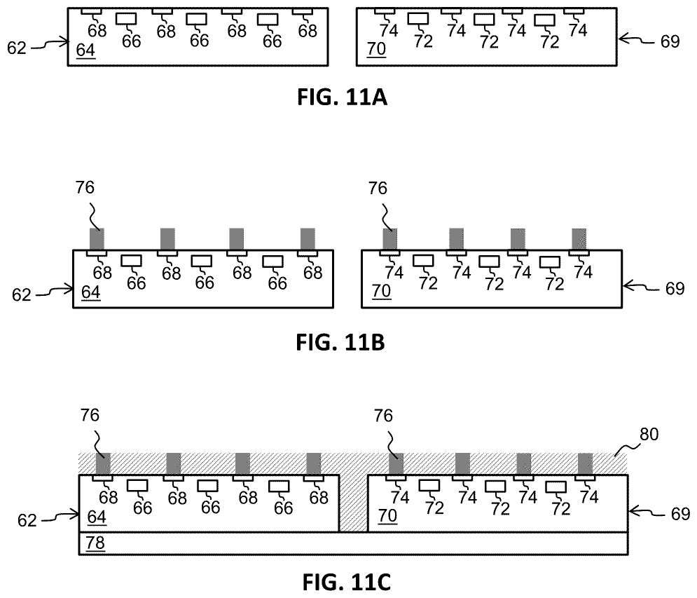

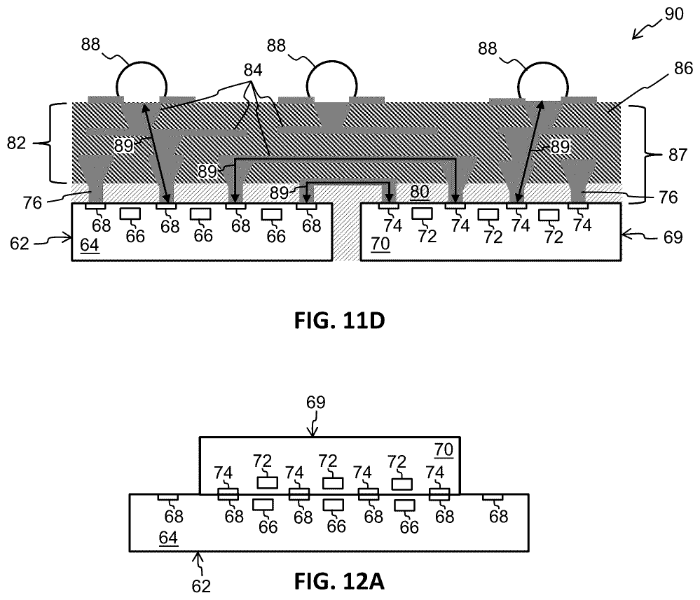

As the sizes of components continue to shrink, it has become more difficult to form functional blocks with non-planar MOSFET devices such as FinFET logic devices and GAAFET devices on the same substrate as functional blocks with planar MOSFET devices such as planar split gate memory cells. Therefore, a semiconductor device is disclosed, where functional blocks that include non-planar MOSFET devices are formed on a first substrate, functional blocks that include planar devices are formed on a second substrate, and where the first and second substrates are electrically connected together. FIGS. 11A-11D illustrate a first example of a method of forming the semiconductor device. The method begins with providing a first die 62 and a second die 69, as illustrated in FIG. 11A. The first die 62 comprises a first substrate 64 (e.g., a semiconductor substrate such as silicon) and one or more functional blocks formed thereon (which can be covered in insulation material), wherein the functional blocks include non-planar MOSFET devices 66 electrically connected to contact pads 68. The non-planar MOSFET devices 66 can include FinFET logic devices 40 of the type illustrated in FIGS. 9A-9B, GAAFET logic devices 50 of the type illustrated in FIGS. 10A-10B, or a combination of both. Functional blocks that can be formed on first substrate 64 with non-planar MOSFET devices 66 can include one or more of the following: a CPU, a GPU, an accelerator, and SRAM, without limitation. The second die 69 comprises a second substrate 70 (e.g., a semiconductor substrate such as silicon) and one or more functional blocks formed thereon (which can be covered in insulation material) that includes planar MOSFET devices 72 electrically connected to contact pads 74. The planar MOSFET devices 72 can include planar split gate memory cells 10 of the types illustrated in FIGS. 1-7, planar logic devices 30 of the type illustrated in FIG. 8, or a combination of both. Functional blocks that can be formed on second substrate 70 with planar MOSFET devices 72 can include one or more of the following: a non-volatile memory cell array, analog to digital converter, digital to analog converter, Ethernet interface, serial peripheral interface, USB interface, local interconnect network, controller area network bus, and an inter-integrated circuit protocol circuit, without limitation.

Respective conductive pillars 76 are formed on (and in electrical contact with) the contact pads 68 of first substrate 64 and contact pads 74 of second substrate 70, as illustrated in FIG. 11B. Conductive pillars 76 can be formed by a conductive material damascene process. For example, photolithography patterning (depositing photo resist, selective exposure and removal of photo resist, leaving trenches in the photoresist) can be performed, followed by filling the trenches with conductive material such as copper by deposition. First and second substrates 64 and 70 are attached to a carrier 78, and a first insulation material 80 (e.g., molding) is formed on and between first and second substrates, and planarized to leave the tops of conductive pillars 76 exposed, as shown in FIG. 11C. Redistribution layers (RDLs) 82 are formed on the first insulation material 80, where the RDLs 82 include conductive wiring 84 (e.g., copper) extending through second insulation material 86 (e.g., polyimide). The conductive wiring 84 includes a plurality of interconnected segments, some extending horizontally while others extending vertically. Respective portions of conductive wiring 84 are in electrical contact with respective conductive pillars 76, with some portions of conductive wiring 84 terminating at the top of the second insulation material 86. Contacts 88 (e.g., solder balls) can be formed at the top of the second insulation material 86 and in electrical contact with the respective portions of conductive wiring 84, as shown in FIG. 11D (after removal of the carrier 78).

The conductive wiring 84 and conductive pillars 76 form a plurality of paths of conductive material 89 between selected ones of the contact pads 68/74 and selected ones of the contacts 88. The paths of conductive material 89 extend through insulation material 87 (i.e., first and second insulation materials 80, 86). For example, one of the paths of conductive material 89 can electrically connect one of the contact pads 68 to a first one of the contacts 88, another one of the paths of conductive material 89 can electrically connect one of the contact pads 74 to a second one of the contacts 88, and still another one of the paths of conductive material 89 can electrically connect one of the contact pads 68 to one of the contact pads 74. While insulation material 87 is shown as comprising two different insulation materials 80, 86, insulation material 87 could be formed with a single material (i.e., first and second insulation materials 80, 86 can be the same material).

FIG. 11D illustrates the final structure of a semiconductor device 90, which includes both planar and non-planar MOSFET devices. The non-planar MOSFET devices 66 are formed on first substrate 64 of first die 62, while planar MOSFET devices 72 are formed on second substrate 70 of second die 69. The first die 62 and the second die 69 are electrically connected to each other and to contacts 88 to form semiconductor device 90. There are many advantages to this configuration. MOSFET processing techniques specifically tailored for non-planar devices can be used to form non-planar MOSFET devices 66 (e.g., FinFET logic devices 40 of FIGS. 9A-9B, GAAFET logic devices 50 of FIGS. 10A-10B) on first substrate 64, while MOSFET processing techniques specifically tailored for planar devices can be used to form planar MOSFET devices 72 (e.g., planar memory cells 10 and arrays of such memory cells of FIGS. 1-7, planar logic device 8 of FIG. 8) on second substrate 70. This avoids having to combine process flows for forming planar and non-planar devices (which can interfere with each other) on the same substrate. The first and second substrates 64 and 70 are positioned laterally side by side. External voltages and signaling for both first and second die 62 and 69 of the semiconductor device 90 are provided via contacts 88 and paths of conductive material 89. Therefore, while the form factor of semiconductor device 90 including its contacts 88 are similar that of a single substrate device, the formation of semiconductor device 90 enjoys the manufacturing advantages of being able to form the non-planar MOSFET devices on first substrate 64 separately from the planar MOSFET devices on second substrate 70. The number of paths of conductive material 89 connecting the non-planar MOSFET devices 66 of substrate 64 to the planar MOSFET devices 72 of substrate 70 provided by RDLs 82 can be the same as the number of lines connecting comparable devices should they all be formed on the same substrate.

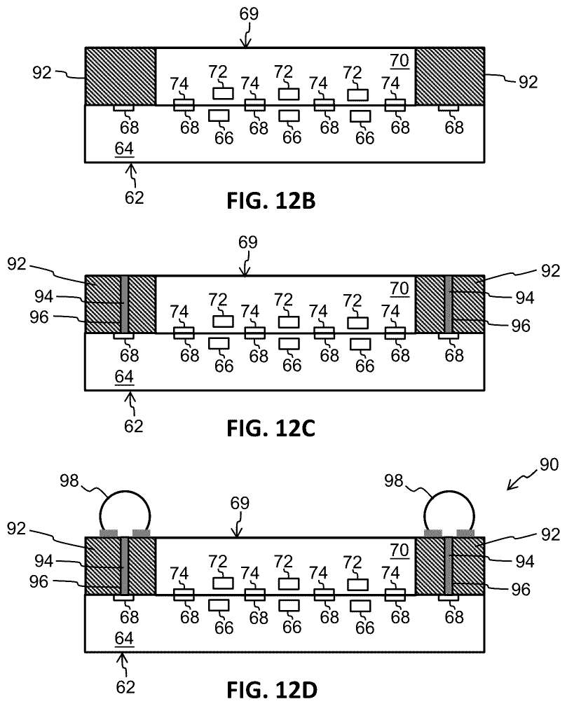

FIGS. 12A-12D illustrate a second example of forming the semiconductor device 90. The method begins with the first and second dies 62 and 69 shown in FIG. 11A. The sides of first and second die 62 and 69 containing respective contact pads 68 and 74 are oriented to face each other. Selected ones of the contact pads 68 of first substrate 64 and contact pads 74 of second substrate 70 that are intended to be electrically connected to each other are aligned to each other and then the first and second substrates 64 and 70 are pressed against each other so that the respective contact pads 68, 74 make physical contact with each other, as shown in FIG. 12A. An anneal process can be performed to bond respective contact pads 68 and contact pads 74 to each other (i.e., respective contact pads 68 and 74 are physically bonded to each other). In this example, some of the contact pads 68 of first substrate 64 are left exposed. Via insulation material 92 (e.g., molding) is formed over the structure, and can be planarized by a chemical mechanical polish, leaving the previously exposed contact pads 68 covered by via insulation material 92, as shown in FIG. 12B. Conductive vias 94 are formed through via insulation material 92 by photo lithography patterning, where via holes 96 are formed through via insulation material 92 to expose the contact pads 68 covered by via insulation material 92, and the via holes 96 are filled with a conductive material (e.g., a metal), leaving conductive vias 94 in electrical contact with contact pads 68, as shown in FIG. 12C. Contacts 98 (e.g., solder balls) can be formed at the top of the via insulation material 92 and in electrical contact with the conductive vias 94, as shown in FIG. 12D.

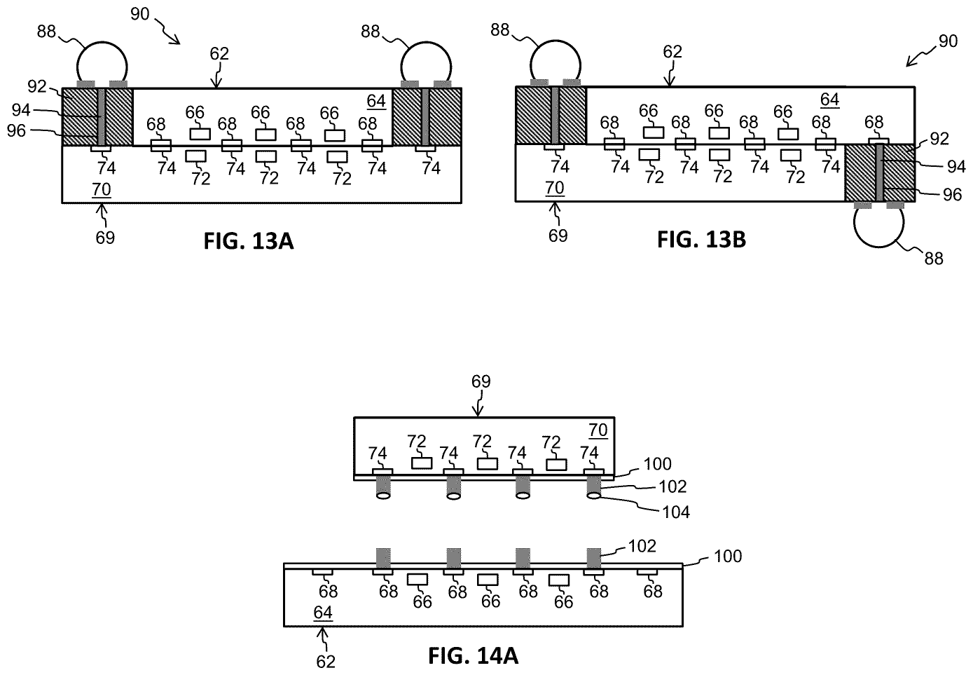

FIG. 12D illustrates the final structure of a semiconductor device 90, with the non-planar MOSFET devices 66 formed on first substrate 64 of first die 62, and planar MOSFET devices 72 formed on second substrate 70 of second die 69. This example enjoys the same advantages set forth with respect to the example of FIG. 11D. Additionally, voltages and signals are shared between first die 62 and second die 69 through respective contact pads 68 and 74 physically bonded to each other. External voltages and signaling for both first die 62 and second die 69 of the semiconductor device 90 are provided through contacts 98, conductive vias 94 and contact pads 68 of first die 62. While the example of FIG. 12D includes conductive vias 94 electrically connected to contact pads 68 of first die 62, the conductive vias 94 can be electrically connected to contact pads 74 of second die 69, as shown in FIG. 13A, or can be electrically connected to both contact pads 68 of first die 62 and to contact pads 74 of second die 69, as shown in FIG. 13B.

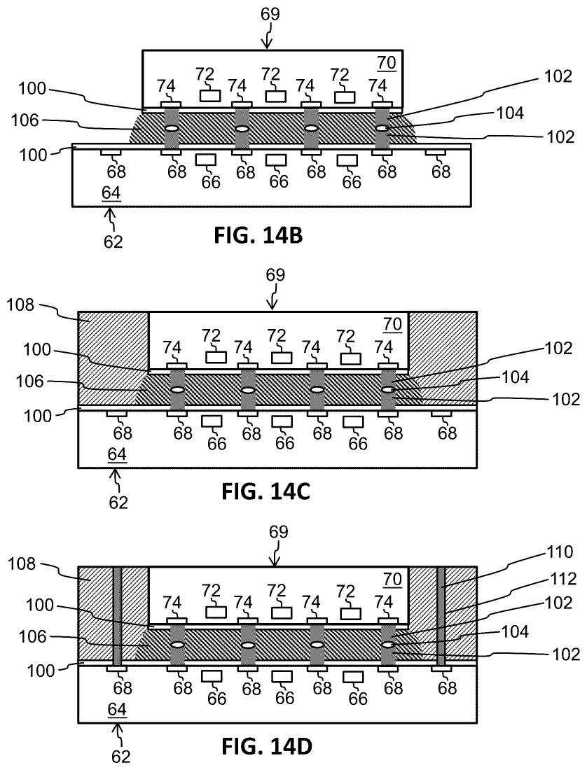

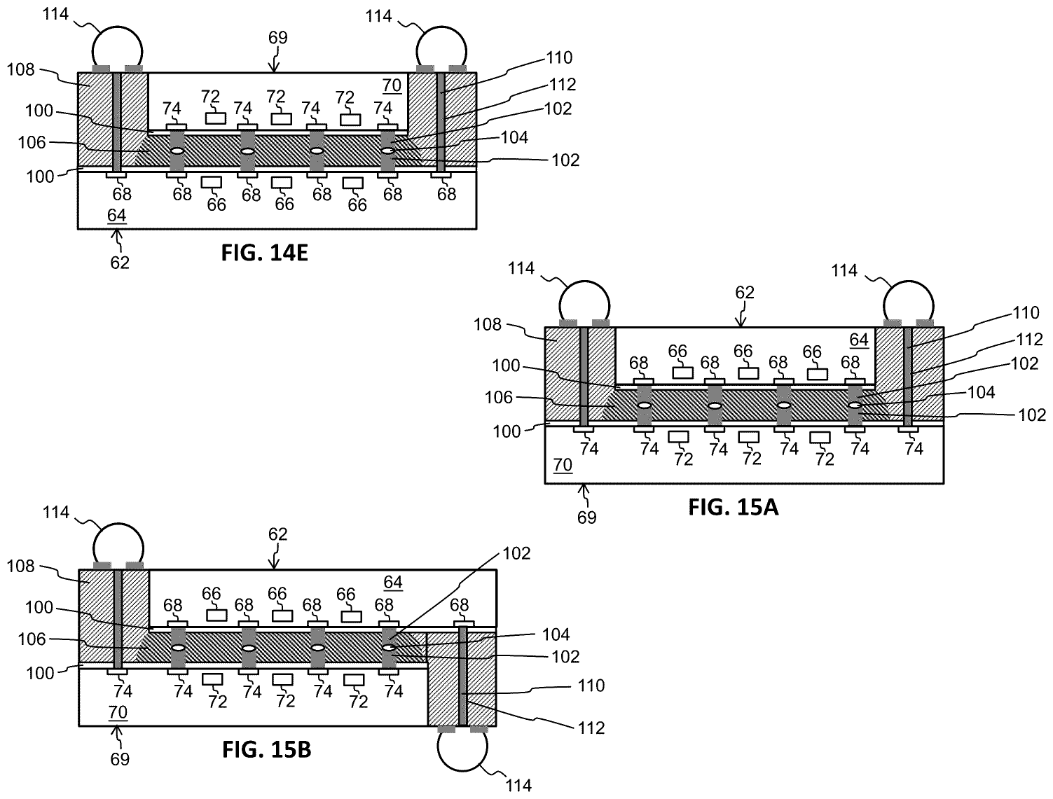

FIGS. 14A-14E illustrate a third example of forming the semiconductor device 90. The method begins with the first die 62 and second die 69 shown in FIG. 11A. An insulation layers 100 are formed on the sides of first die 62 and second die 69 containing contact pads 68 and 74 (i.e., insulation layer 100 covers contact pads 68 and 74). Conductive pillars 102 are formed on (and in electrical contact with) the contact pads 68 of first substrate 64 and contact pads 74 of second substrate 70. Conductive pillars 102 can be formed by a conductive material damascene process. For example, photolithography patterning (depositing photo resist, selective exposure and removal of photo resist, leaving trenches in the photoresist) can be performed, removal of insulation layer 100 under the trenches, followed by filling the trenches with conductive material such as copper by deposition. A solder cap process can be performed to form solder 104 on the ends of conductive pillars 102 for one of the die (e.g., second die 69), as illustrated in FIG. 14A.

Selected ones of the conductive pillars 102 of die 62 and conductive pillars 102 of die 69 that are intended to be electrically connected to each other are aligned to each other, and then brought into contact. An anneal may be used to cause the solder 104 to bond opposing conductive pillars 102. Fill insulation material 106 (e.g., solder paste) can be used to fill the open space between first die 62 and second die 69, including surrounding conductive pillars 102, as illustrated in FIG. 14B. In this example, some of the contact pads 68 of first substrate 64 are not covered by the insulation material 106. Via insulation material 108 (e.g., molding) is formed over the structure, and can be planarized by a chemical mechanical polish, leaving the contact pads 68 previously exposed by fill insulation material 106 covered by via insulation material 108, as shown in FIG. 14C. Conductive vias 110 are formed through via insulation material 108 by photo lithography patterning, where via holes 112 are formed through via insulation material 108 and insulation layer 100 to expose the contact pads 68 previously covered by via insulation material 108, and the via holes 112 are filled with a conductive material (e.g., a metal), leaving conductive vias 110 in electrical contact with contact pads 68, as shown in FIG. 14D. Contacts 114 (e.g., solder balls) can be formed at the top of the via insulation material 108 and in electrical contact with the conductive vias 110, as shown in FIG. 14E.

FIG. 14E illustrates the final structure of a semiconductor device 90, with the non-planar MOSFET devices 66 formed on first substrate 64 of first die 62, and planar MOSFET devices 72 formed on second substrate 70 of second die 69. This example enjoys the same advantages set forth with respect to the example of FIG. 12D. While the example of FIG. 14E includes conductive vias 110 electrically connected to contact pads 68 of first die 62, the conductive vias 110 can be electrically connected to contact pads 74 of second die 69, as shown in FIG. 15A, or can be electrically connected to both contact pads 68 of first die 62 and to contact pads 74 of second die 69, as shown in FIG. 15B.

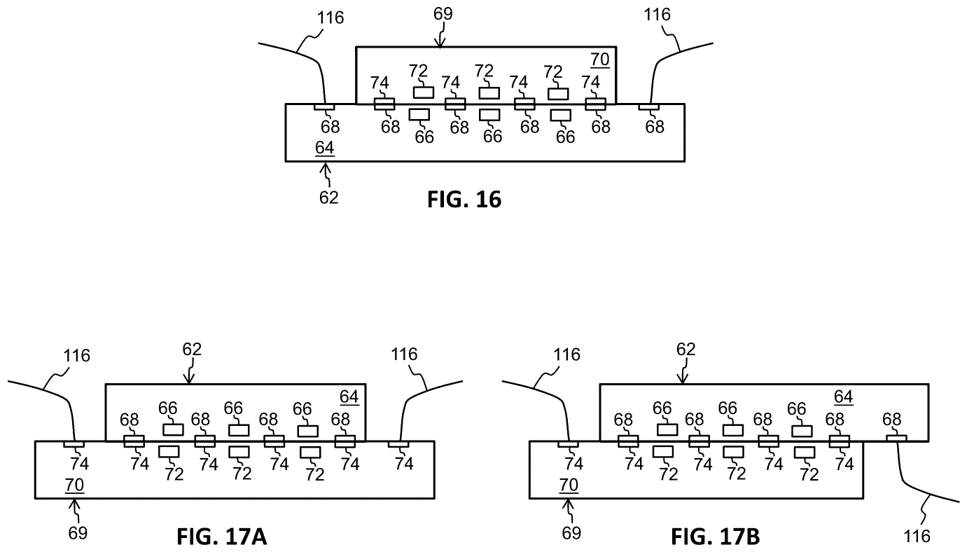

FIG. 16 illustrates another example of a semiconductor device, which is the same structure shown in FIG. 12A. However, instead of the processing shown in FIGS. 12B-12D, wires 116 are connected to contact pads 68. For some applications, wire bonding by connecting wires 116 to contact pads 68 can be simpler and more desirable than forming conductive vias through insulation material. While FIG. 16 includes wires 116 electrically connected to contact pads 68 of first die 62, the wires 116 can be electrically connected to contact pads 74 of second die 69, as shown in FIG. 17A, or can be electrically connected to both contact pads 68 of first die 62 and to contact pads 74 of second die 69, as shown in FIG. 17B.

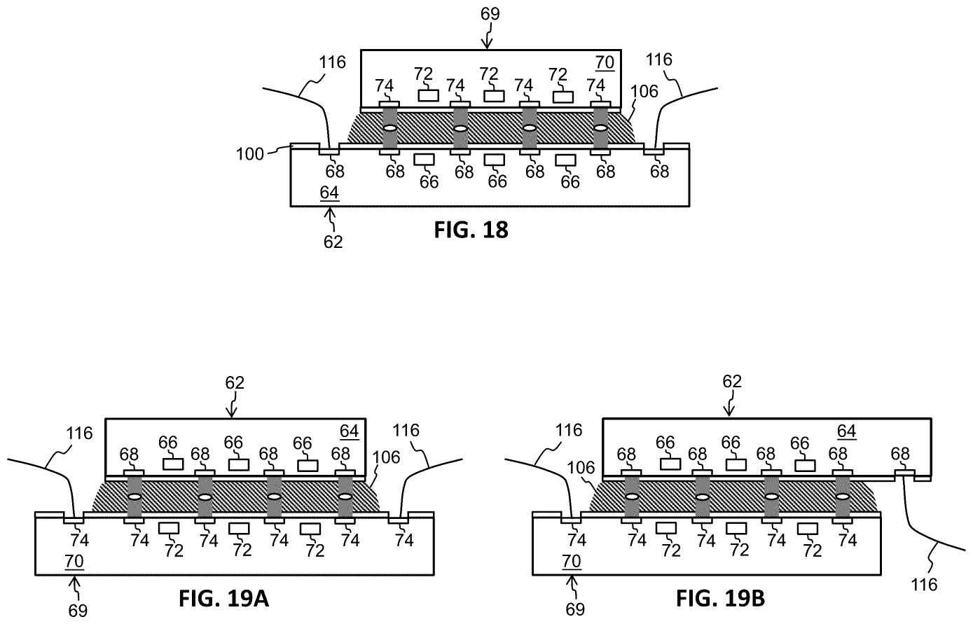

FIG. 18 illustrates another example of a semiconductor device, which is the same structure shown in FIG. 14B. However, instead of the processing shown in FIGS. 14C-14E, portions of insulation layer 100 over contact pads 68 are removed, and wires 116 are connected to contact pads 68. For some applications, wire bonding by connecting wires 116 to contact pads 68 can be simpler and more desirable than forming conductive vias through insulation material. While FIG. 18 includes wires 116 electrically connected to contact pads 68 of first die 62, the wires 116 can be electrically connected to contact pads 74 of second die 69, as shown in FIG. 19A, or can be electrically connected to both contact pads 68 of first die 62 and to contact pads 74 of second die 69, as shown in FIG. 19B.

It is to be understood that the present disclosure is not limited to the example(s) described above and illustrated herein, but encompasses any and all variations falling within the scope of any claims. For example, references to the present disclosure or invention or examples herein are not intended to limit the scope of any claim or claim term, but instead merely make reference to one or more features that may be covered by one or more claims. Materials, processes and numerical examples described above are examples only, and should not be deemed to limit any claims.

What is claimed is:

1. A semiconductor device, comprising:
a first die comprising:
a first substrate,
non-planar MOSFET devices formed on the first substrate, and
first contact pads electrically connected to the non-planar MOSFET devices;
a second die comprising:
a second substrate,
planar MOSFET devices formed on the second substrate, and
second contact pads electrically connected to the planar MOSFET devices;
insulation material formed on the first and second substrates;
contacts formed on the insulation material; and
paths of conductive material extending through the insulation material, and electrically connected to respective ones of the contacts, the first contact pads and the second contact pads.

2. The semiconductor device of claim 1, wherein:
a first plurality of the paths of conductive material are electrically connected to selected ones of the contacts and selected ones of the first contact pads;
a second plurality of the paths of conductive material are electrically connected to selected ones of the contacts and selected ones of the second contact pads; and
a third plurality of the paths of conductive material are electrically connected to selected ones of the first contact pads and selected ones of the second contact pads.

3. The semiconductor device of claim 1, wherein the second die does not include any non-planar MOSFET devices.

4. The semiconductor device of claim 1, wherein the planar MOSFET devices formed on the second substrate include non-volatile memory cells, wherein respective ones of the non-volatile memory cells comprises:
a source region and a drain region formed in the second substrate, with a channel region of the second substrate extending between the source region and the drain region and extending along a planar upper surface of the second substrate;
a floating gate disposed over and insulated from a first portion of the channel region; and
a select gate disposed over and insulated from a second portion of the channel region.

5. The semiconductor device of claim 4, wherein the respective ones of the non-volatile memory cells comprises:
an erase gate disposed over and insulated from the source region.

6. The semiconductor device of claim 5, wherein the respective ones of the non-volatile memory cells comprises:
a control gate disposed over and insulated from the floating gate.

7. The semiconductor device of claim 1, wherein the planar MOSFET devices formed on the second substrate include logic devices, wherein respective ones of the logic devices comprises:
a source region and a drain region formed in the second substrate, with a channel region of the second substrate extending between the source region and the drain region and extending along a planar upper surface of the second substrate; and
a conductive gate disposed over and insulated from the channel region.

8. The semiconductor device of claim 1, wherein the non-planar MOSFET devices formed on the first substrate include FinFET logic devices, wherein respective ones of the FinFET logic devices comprises:
a fin of semiconductor material extending from a surface of the first substrate, wherein the fin includes side surfaces terminating in a top surface;
a source region and a drain region formed in the fin of semiconductor material, with a channel region extending between the source region and the drain region, wherein the channel region extends along the side surfaces and the top surface of the fin of semiconductor material; and
a conductive gate that wraps around and is insulated from the channel region of the top surface and the side surfaces of the fin of semiconductor material.

9. The semiconductor device of claim 1, wherein the non-planar MOSFET devices formed on the first substrate include gate-all-around logic devices, wherein respective ones of the gate-all-around logic devices comprises:
a conductive gate disposed over and insulated from the first substrate;
a wire of semiconductor material extending through the conductive gate; and
a source region and a drain region formed in the wire of semiconductor material, with a channel region extending between the source region and the drain region, wherein the channel region extends through the conductive gate.

10. A semiconductor device, comprising:
a first die comprising:
a first substrate,
non-planar MOSFET devices formed on the first substrate, and
first contact pads electrically connected to the non-planar MOSFET devices;
a second die comprising:
a second substrate,
planar MOSFET devices formed on the second substrate, and
second contact pads electrically connected to the planar MOSFET devices;
wherein selected ones of the first contact pads are physically bonded to selected ones of the second contact pads; and
a conductive via or a wire in electrical contact with one of the first or second contact pads.

11. The semiconductor device of claim 10, comprising:
via insulation material disposed over the one of the first or second contact pads; and
the conductive via is in electrical contact with the one of the first or second contact pads, wherein the conductive via extends through the insulation material.

12. The semiconductor device of claim 10, wherein the wire is in electrical contact with the one of the first or second contact pads.

13. The semiconductor device of claim 10, wherein the second die does not include any non-planar MOSFET devices.

14. The semiconductor device of claim 10, wherein the planar MOSFET devices formed on the second substrate include non-volatile memory cells, wherein respective ones of the non-volatile memory cells comprises:
a source region and a drain region formed in the second substrate, with a channel region of the second substrate extending between the source region and the drain region and extending along a planar upper surface of the second substrate;
a floating gate disposed over and insulated from a first portion of the channel region; and
a select gate disposed over and insulated from a second portion of the channel region.

15. The semiconductor device of claim 14, wherein the respective ones of the non-volatile memory cells comprises:
an erase gate disposed over and insulated from the source region.

16. The semiconductor device of claim 15, wherein the respective ones of the non-volatile memory cells comprises:
a control gate disposed over and insulated from the floating gate.

17. The semiconductor device of claim 10, wherein the planar MOSFET devices formed on the second substrate include logic devices, wherein respective ones of the logic devices comprises:
a source region and a drain region formed in the second substrate, with a channel region of the second substrate extending between the source region and the drain region and extending along a planar upper surface of the second substrate; and
a conductive gate disposed over and insulated from the channel region.

18. The semiconductor device of claim 10, wherein the non-planar MOSFET devices formed on the first substrate include FinFET logic devices, wherein respective ones of the FinFET logic devices comprises:
a fin of semiconductor material extending from a surface of the first substrate, wherein the fin includes side surfaces terminating in a top surface;
a source region and a drain region formed in the fin of semiconductor material, with a channel region extending between the source region and the drain region, wherein the channel region extends along the side surfaces and the top surface of the fin of semiconductor material; and
a conductive gate that wraps around and is insulated from the channel region of the top surface and the side surfaces of the fin of semiconductor material.

19. The semiconductor device of claim 10, wherein the non-planar MOSFET devices formed on the first substrate include gate-all-around logic devices, wherein respective ones of the gate-all-around logic devices comprises:
a conductive gate disposed over and insulated from the first substrate;
a wire of semiconductor material extending through the conductive gate; and
a source region and a drain region formed in the wire of semiconductor material, with a channel region extending between the source region and the drain region, wherein the channel region extends through the conductive gate.

20. A semiconductor device, comprising:
a first die comprising:
a first substrate,
non-planar MOSFET devices formed on the first substrate, and
first contact pads electrically connected to the non-planar MOSFET devices;
a second die comprising:
a second substrate,
planar MOSFET devices formed on the second substrate, and
second contact pads electrically connected to the planar MOSFET devices;
wherein selected ones of the first contact pads are electrically connected to selected ones of the second contact pads by conductive pillars; and
a conductive via or a wire in electrical contact with one of the first or second contact pads.

21. The semiconductor device of claim 20, comprising:
insulation material disposed over the one of the first or second contact pads; and
the conductive via is in electrical contact with the one of the first or second contact pads, wherein the conductive via extends through the insulation material.

22. The semiconductor device of claim 20, wherein the wire is in electrical contact with the one of the first or second contact pads.

23. The semiconductor device of claim 20, comprising:
fill insulation material disposed between the first and second substrates, wherein the conductive pillars extend through the insulation material.

24. The semiconductor device of claim 20, wherein the second die does not include any non-planar MOSFET devices.

25. The semiconductor device of claim 20, wherein the planar MOSFET devices formed on the second substrate include non-volatile memory cells, wherein respective ones of the non-volatile memory cells comprises:
a source region and a drain region formed in the second substrate, with a channel region of the second substrate extending between the source region and the drain region and extending along a planar upper surface of the second substrate;
a floating gate disposed over and insulated from a first portion of the channel region; and
a select gate disposed over and insulated from a second portion of the channel region.

26. The semiconductor device of claim 25, wherein the respective ones of the non-volatile memory cells comprises:
an erase gate disposed over and insulated from the source region.

27. The semiconductor device of claim 26, wherein the respective ones of the non-volatile memory cells comprises:
a control gate disposed over and insulated from the floating gate.

28. The semiconductor device of claim 20, wherein the planar MOSFET devices formed on the second substrate include logic devices, wherein respective ones of the logic devices comprises:
a source region and a drain region formed in the second substrate, with a channel region of the second substrate extending between the source region and the drain region and extending along a planar upper surface of the second substrate; and
a conductive gate disposed over and insulated from the channel region.

29. The semiconductor device of claim 20, wherein the non-planar MOSFET devices formed on the first substrate include FinFET logic devices, wherein respective ones of the FinFET logic devices comprises:
a fin of semiconductor material extending from a surface of the first substrate, wherein the fin includes side surfaces terminating in a top surface;
a source region and a drain region formed in the fin of semiconductor material, with a channel region extending between the source region and the drain region, wherein the channel region extends along the side surfaces and the top surface of the fin of semiconductor material; and
a conductive gate that wraps around and is insulated from the channel region of the top surface and the side surfaces of the fin of semiconductor material.

30. The semiconductor device of claim 20, wherein the non-planar MOSFET devices formed on the first substrate include gate-all-around logic devices, wherein respective ones of the gate-all-around logic devices comprises:
a conductive gate disposed over and insulated from the first substrate;
a wire of semiconductor material extending through the conductive gate; and
a source region and a drain region formed in the wire of semiconductor material, with a channel region extending between the source region and the drain region, wherein the channel region extends through the conductive gate.
